(19) United States
(12) Patent Application Publication
(10) Pub. No.: US 2013/0196019 A1
(43) Pub. Date: Aug. 1, 2013

(54) SILICON-CONTAINING BLOCK CO-POLYMERS, METHODS FOR SYNTHESIS AND USE

(71) Applicants: C. Grant Willson, Austin, TX (US); Christopher M. Bates, Austin, TX (US); Jeffrey Strahan, Austin, TX (US); Christopher John Ellison, Austin, TX (US); Brennen Mueller, Atlanta, GA (US)

(72) Inventors: C. Grant Willson, Austin, TX (US); Christopher M. Bates, Austin, TX (US); Jeffrey Strahan, Austin, TX (US); Christopher John Ellison, Austin, TX (US); Brennen Mueller, Atlanta, GA (US)

(73) Assignee: National University of Sinapore, Singapore (SG)

(21) Appl. No.: 13/583,369

(22) PCT Filed: Mar. 17, 2011
(86) PCT No.: PCT/US11/28867

§ 371 Date: Oct. 10, 2012

Related U.S. Application Data
(60) Provisional application No. 61/315,235, filed on Mar. 18, 2010.

(51) Int. Cl. B05D 3/10; H01L 21/02

(52) U.S. Cl. CPC B05D 3/107; H01L 21/02
USPC 425/470; 216/11

(57) ABSTRACT

The present invention describes the synthesis of silicon-containing monomers and copolymers. The synthesis of a monomer, trimethyl-(2-methylenebut-3-enyl)silane (TMSI) and subsequent synthesis of diblock copolymer with styrene, forming polystyrene-block-polytrimethylsilyl isoprene, and synthesis of diblock copolymer Polystyrene-block-polymethacryloxymethyltrimethylsilane or PS-b-P(MTMSMA). These silicon containing diblock copolymers have a variety of uses. One preferred application is as novel imprint template material with sub-100 nm features for lithography.

### FIELD OF THE INVENTION

The present invention relates to a heteropolymer or copolymer derived from two (or more) monomeric species, at least one of which incorporates a silicon atom. Such compounds have many uses including multiple applications in the semiconductor industry including patterning of templates for use in nanoimprint lithography.

### BACKGROUND OF THE INVENTION

The improvement in areal density in hard disk drives using conventional multigrain media is currently bound by the superparamagnetic limit [1]. Bitpatterned media can circumvent this limitation by creating isolated magnetic islands separated by a nonmagnetic material. Nanoimprint lithography is an attractive solution for producing bit patterned media if a template can be created with sub-25 nm features [2]. Resolution limits in optical lithography and the prohibitive cost of electron beam lithography due to slow throughput [3] necessitate a new template patterning process. The self-assembly of diblock copolymers into well-defined structures [4] on the order of 5-100 nm produces features on the length scale required for production of bit patterened media. This is most efficiently accomplished by using the diblock copolymers to produce templates for imprint lithography [5]. With the availability of the proper template, imprint lithography can be employed to produce bit patterned media efficiently. Previous research has targeted a block copolymers that produce hexagonally packed cylindrical morphology with selective silicon incorporation into one block for etch resistance [6] through post-polymerization SiO₂ growth [7], silica deposition using supercritical CO₂ [8], and silicon-containing ferrocenyl monomers [9]. What is needed is method to create an imprint template with sub-100 nm features that can be etched.

### SUMMARY OF THE INVENTION

The present invention contemplates silicon-containing compositions, methods of synthesis, and methods of use. More specifically, the present invention relates to a heteropolymer or copolymer derived from two (or more) monomeric species, at least one of which comprising silicon. Such compounds have many uses including multiple applications in the semiconductor industry including making templates for nanoimprint lithography.

In one embodiment, the invention relates to a method of synthesizing a silicon-containing block copolymer, comprising: a) providing first and second monomers (and, in some embodiments, additional monomers), said first monomer comprising a silicon atom and said second monomer being a hydrocarbon monomer (lacking silicon) that can be polymerized; b) treating said second monomer under conditions such that reactive polymer of said second monomer is formed; and c) reacting said first monomer with said reactive polymer of said second monomer under conditions such that said silicon-containing block copolymer is synthesized (e.g. a diblock, triblock etc.). In one embodiment, said second monomer is styrene and said reactive polymer is reactive polystyrene. In one embodiment, said reactive polystyrene is anionic polystyrene. In one embodiment, said first monomer is trimethyl-(2-methylene-but-3-enyl)silane. In one embodiment, said first monomer was synthesized in a Kumada coupling reaction (see reference 10) of chloroprene and (trimethylsilyl)-methylmagnesium chloride. In one embodiment, the conditions of step b) comprise polymerization in cyclohexane. In one embodiment, the method further comprises d) precipitating said silicon-containing block copolymer in methanol. In one embodiment, said silicon-containing block copolymer is PS-b-PTMSI. In one embodiment, said first monomer is a silicon-containing methacrylate. In one embodiment, said first monomer is methacryloxymethyltrimethylsilane (MTMSMA). In one embodiment, said silicon-containing block copolymer is Polystyrene-block-polymethacryloxymethyltrimethylsilane or, more simply, PS-b-P(MTMSMA). In one embodiment, said second monomer is a methacrylate. In one embodiment, said second monomer is an epoxide. In one embodiment, said second monomer is a styrene derivative. In one embodiment, said styrene derivative is p-methylstyrene. In one embodiment, said styrene derivative is p-chlorostyrene. In one embodiment, the silicon-containing block copolymer is applied to a surface, for example, by spin coating, preferably under conditions such that physical features, such as nanostructures that are less than 100 nm in size (and preferably 50 nm or less in size), are formed on the surface. Thus, in one embodiment, the method further comprises the step d) coating a surface with said block copolymer so as to create a block copolymer film. In one embodiment, the method further comprises the step e) treating said film under conditions such that nanostructures form. In one embodiment, said nanostructures comprise cylindrical structures, said cylindrical structures being substantially vertically aligned with respect to the plane of the surface. In one embodiment, said treating comprises exposing said coated surface to a saturated atmosphere of a solvent (a process also known as “annealing”), such as acetone or THF. In one embodiment, said surface is on a silicon wafer. In another embodiment, said treating comprises exposing said coated surface to heat. In one embodiment, the film can have different thicknesses. In one embodiment, said surface is not pre-treated with a cross-linked polymer prior to step d). In one embodiment, said surface is pre-treated with a cross-linked polymer prior to step d). In one embodiment, a third monomer is provided and reacted, and the resulting block copolymer is a triblock copolymer. In one embodiment, the invention contemplates a film made according to the process above. In one embodiment, the method further comprises the step f) etching said nanostructure-containing coated surface.

In one embodiment, the invention relates to a method of synthesizing a silicon-containing block copolymer, comprising: a) providing first and second monomers, said first monomer comprising a hydrocarbon monomer that does not incorporate silicon (i.e. lacking a silicon atom), said second monomer being a monomer that can be polymerized and comprising a silicon atom; b) treating said second monomer under conditions such that reactive polymer of said second monomer is formed; and c) reacting said first monomer with said reactive polymer of said second monomer under conditions such that said silicon-containing block copolymer is synthesized. In one embodiment, said second monomer is a silicon-containing styrene derivative. In one embodiment, said styrene derivative is p-trimethylsilyl styrene. In one embodiment, said second monomer is a silicon-containing methacrylate. In one embodiment, the method further comprises the step d) coating a surface with said block copolymer so as to create a block copolymer film. In one embodiment, the silicon-containing block copolymer is applied to a surface, for example, by spin coating, preferably under conditions such that physical features, such as nanostructures that are less than 100 nm in size (and preferably 50 nm or less in size), are formed on the surface. Thus, in one embodiment, the method further comprises the step e) treating said film under conditions such that nanostructures form. In one embodiment, said nanostructures comprises cylindrical structures, said cylindrical structures being substantially vertically aligned with respect to the plane of the surface. In one embodiment, said treating comprises exposing said coated surface to a saturated atmosphere of a solvent (a process also known as “annealing”) such as acetone or THF. In another embodiment, said treating comprises exposing said coated surface to heat. In one embodiment, the film can have different thicknesses. In one embodiment, said surface is on a silicon wafer. In one embodiment, said surface is not pre-treated with a cross-linked polymer prior to step d). In one embodiment, said surface is pre-treated with a cross-linked polymer prior to step d). In one embodiment, the invention relates to a method wherein a third monomer is provided and said block copolymer is a triblock copolymer. In one embodiment, the invention relates to a film made according to the process above. In one embodiment, the method further comprises the step f) etching said nanostructure-containing coated surface.

In one embodiment, the invention relates to a method forming nanostructures on a surface, comprising: a) providing a silicon-containing block copolymer such as PS-b-P(MTMSMA) and a surface; b) spin coating said block copolymer on said surface to create a coated surface; and c) treating said coated surface under conditions such that nanostructures are formed on said surface. In one embodiment, said nanostructures comprises cylindrical structures, said cylindrical structures being substantially vertically aligned with respect to the plane of the surface. In one embodiment, said treating comprises exposing said coated surface to a saturated atmosphere of a solvent (a process also known as “annealing”) such as acetone or THF. In another embodiment, said treating comprises exposing said coated surface to heat. In one embodiment, the film can have different thicknesses. In one embodiment, said surface is on a silicon wafer. In one embodiment, said surface is not pre-treated with a cross-linked polymer prior to step b). In one embodiment, said surface is pre-treated with a cross-linked polymer prior to step b). In one embodiment, the invention relates to a film made according to the process above. In one embodiment, the method further comprises the step e) etching said nanostructure-containing coated surface.

It is not intended that the present invention be limited to a specific silicon-containing monomer or copolymer. Illustrative monomers are shown in FIG. 12. However, in one embodiment, a method of synthesis is contemplated for synthesizing a silicon-containing monomer, comprising reacting 2-chlorobuta-1,3-diene represented by the structure shown as (A) with ((trimethylsilyl)methyl)magnesium chloride (a Grignard reagent) represented by the structure shown as (B) so as to generate trimethyl-(2-methylenebut-3-enyl)silane represented by the structure (C) (see FIG. 1).

It is not intended that the present invention be limited to a specific monomer or copolymer. Illustrative monomers are shown in FIG. 13. In another embodiment, a method of synthesis is contemplated comprising reacting a monomer such as styrene represented by the structure shown as (D) with sec-butyl lithium so as to generate a polystyrene anion represented by the structure (E) (see FIG. 2). The anionic polystyrene represented by the structure (E) can be further reacted with a silicon-containing monomer such as by the addition of trimethyl-(2-methylenebut-3-enyl)silane under such conditions as to generate a poly(styrene-trimethyl-(2-methylenebut-3-enyl)silane) dibolock copolymer represented by the structure (F) (see FIG. 2).

In another embodiment, a method of synthesis is contemplated comprising reacting a monomer such as styrene represented by the structure shown as (D) with sec-butyl lithium and subsequently with ethene-1,1-diyldibenzene (G) so as to generate a diphenyl ethylene end-capped polystyrene anion represented by the structure (H) (see FIG. 6). The diphenyl ethylene end-capped polystyrene anion represented by the structure (H) can be further reacted with addition of a silicon-containing monomer such as methacryloxymethyltrimethylsilane (MTMSMA) under such conditions as to generate a diblock copolymer, PS-b-P(MTMSMA) represented by the structure (I) (see FIG. 6).

In one embodiment, the invention relates to a method of synthesizing a silicon-containing copolymer, comprising: a) providing first and second monomers, said first monomer being a silicon-functionalized isoprene monomer and said second monomer being a monomer that does not incorporate silicon but can be polymerized such as styrene (e.g. in the case of styrene, it can polymerize because of the vinyl group); b) treating said second monomer under conditions such that a reactive polymer (such anionic as polystyrene) is formed; and c) reacting said first monomer with said reactive polymer (such as anionic polystyrene) under conditions such that said silicon-containing copolymer is synthesized. In one embodiment, said first monomer is trimethyl-(2-methylene-but-3-enyl)silane. In one embodiment, said first monomer was synthesized in a Kumada coupling reaction of chloroprene and (trimethylsilyl)-methylmagnesium chloride. In one embodiment, the conditions of step b) comprise polymerization in cyclohexane. In one embodiment, the conditions of step c) comprise anionic polymerization. In one embodiment the present invention contemplates, a further step comprising d) precipitating said silicon-containing copolymer in methanol. In one embodiment, said silicon-containing copolymer is PS-b-PTMSI, polystyrene-block-polytrimethylsilyl isoprene. In one embodiment, the silicon-containing block copolymer is applied to a surface, for example, by spin coating, preferably under conditions such that physical features, such as nanostructures that are less than 100 nm in size (and preferably 50 nm or less in size), are spontaneously formed on the surface. In one embodiment, the features have very different etch rates such that one block can be etched without substantial etching of the other. In a preferred embodiment, such nanostructures have a cylindrical morphology with the domain spacing of approximately 50 nm or less. In one embodiment, the nanostructures are hexagonally packed. Such conditions for forming nanostructures can involve annealing with heat or solvents. Alternatively, the surface can first be treated with a substance that imparts a desired surface energy such that the nature of the surface treatment controls or enables nanostructure development. Alternatively, the conditions can involve varying the thickness of the applied silicon-containing copolymer. However the nanostructures are made, in one embodiment, the method further comprises etching said nanostructures.

In one embodiment, the invention relates to a method of synthesizing a silicon-containing copolymer, comprising: a) providing first and second monomers, said first monomer being a silicon-containing methacrylate and said second monomer being a monomer that does not incorporate the element silicon and can polymerize such as styrene; b) treating said second monomer under conditions such that a reactive polymer such as polystyrene anion is formed; and c) reacting said first monomer with said reactive polymer (e.g. polystyrene anion) under conditions such that said silicon-containing copolymer is synthesized thus producing a block copolymer. In one embodiment, said first monomer is methacryloxymethyltrimethylsilane (MTMSMA). In one embodiment, the conditions of step c) comprise anionic polymerization. In one embodiment, further comprising d) precipitating said silicon-containing copolymer. In one embodiment, said silicon-containing copolymer is PS-b-P(MTMSMA).

In one embodiment, the invention relates to a method of forming nanostructures on a surface, comprising: a) providing a silicon-containing copolymer such as the PS-b-P(MTMSMA) copolymer and a surface; b) spin coating said copolymer on said surface to create a coated surface; and c) treating said coated surface under conditions such that nanostructures are formed on said surface. In one embodiment, said nanostructures comprise cylindrical structures, said cylindrical structures being substantially vertically aligned with respect to the plane of the surface. In one embodiment, said treating comprises exposing said coated surface to a saturated atmosphere of solvents such as acetone or THF (or other solvent that can dissolve at least one of the blocks in the copolymer and has a high vapor pressure at room temperature, including but not limited to toluene, benzene, etc.) In one embodiment, said surface is on a silicon wafer. In one embodiment, said surface is not pre-treated with a cross-linked polymer prior to step b). In one embodiment, said surface is pre-treated with a cross-linked polymer prior to step b). In one embodiment, nanostructures less than 100 nm in size (and preferably 50 nm or less) are made with the copolymer by annealing using heat or solvents (as described herein). In a preferred embodiment, such nanostructures are hexagonally packed cylindrical morphology with the domain spacing of approximately 50 nm or less. However the nanostructures are made, in one embodiment, the method further comprises etching said nanostructures. In one embodiment, the present invention contemplates compositions comprising thin films (e.g. spin-coated films) of silicon-containing copolymers comprising such nanostructures, e.g. films deposited on a surface.

Many combinations of diblock (or triblock or more) copolymers can be made. For example, the illustrative silicon-containing monomers (FIG. 12) can be combined with any one or more of the hydrocarbon monomers (FIG. 13) lacking silicon. Whatever the combination, it is preferred that a block copolymer contain over 12 wt % silicon in one block. This provides the etch selectivity to yield a 3-D pattern of self-assembled nanofeatures. Polymerization of these monomers can be done using a variety of methods. For example, epoxide polymers can be made using the methods of Hillmyer and Bates, Macromolecules 29:6994 (1996). Polymers of trimethylsilyl styrene are described by Harada et al., J. Polymer Sci. 43:1214 (2005) and Misichronis et al., Int. J. Polymer Analysis and Char. 13:136 (2008). Polymerization of the TBDMSO-Styrene monomer is described by Hirao, A., Makromolecular Chem. Rapid. Commun., 3: 941 (1982).

### BRIEF DESCRIPTION OF THE DRAWINGS

For a more complete understanding of the features and advantages of the present invention, reference is now made to the detailed description of the invention along with the accompanying figures.

FIG. 1 shows the synthesis of TMSI monomer. A non-styrene derivative with a lower boiling point for easier purification, the isoprene product monomer (TMSI) was synthesized via a Kumada coupling [10].

FIG. 2 shows the synthesis of PS-b-PTMSI.

FIG. 3 shows a Gel Permeation Chromatography (GPC) Chromatogram of the PS aliquot (red) and PS-b-PTMSI (green).

FIG. 4 shows a ¹H NMR spectrum of PS-b-PTMSI. The integral values were enlarged for clarity; numerical figures are shown in Table 2.

FIG. 5 shows a Differential Scanning Calorimeter (DSC) trace of PS-b-PTMSI.

FIG. 6 shows the anionic synthesis of PS-b-P(MTMSMA).

FIG. 7 shows the ¹H-NMR of PS-b-P(MTMSMA).

FIG. 8 shows a Gel Permeation Chromatography (GPC) chromatograms of PS aliquot (red) and PS-b-P(MTMSMA) (green).

FIG. 9 shows the Small Angle X-ray Scattering (SAXS) analysis of a sample of PS-b-P(MTMSMA).

FIG. 10 shows a THF annealed film with parallel orientation.

FIG. 11 show an acetone annealed film with perpendicular orientation.

FIG. 12 shows the structures of illustrative silicon-containing monomers.

FIG. 13 shows the structures of illustrative hydrocarbon monomers (lacking silicon).

Table 1 shows a Gel Permeation Chromatography (GPC) characterization of PS-b-PTMSI.

Table 2 shows ¹H NMR data for PS-b-PTMSI.

### DEFINITIONS

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not delimit the invention, except as outlined in the claims.

In addition, atoms making up the compounds of the present invention are intended to include all isotopic forms of such atoms. Isotopes, as used herein, include those atoms having the same atomic number but different mass numbers. By way of general example and without limitation, isotopes of hydrogen include tritium and deuterium, and isotopes of carbon include ¹³C and ¹⁴C. Similarly, it is contemplated that one or more carbon atom(s) of a compound of the present invention may be replaced by a silicon atom(s). Furthermore, it is contemplated that one or more oxygen atom(s) of a compound of the present invention may be replaced by a sulfur or selenium atom(s).

Trimethyl-(2-methylene-but-3-enyl)silane is represented by the following structure:

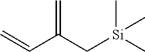

and abbreviated (TMSI) and whose polymeric version is

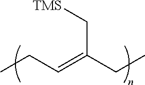

and is abbreviated P(TMSI).

Polystyrene anion is represented by the following structure:

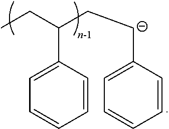

Polystyrene-block-polytrimethylsilyl isoprene is represented by the following structure:

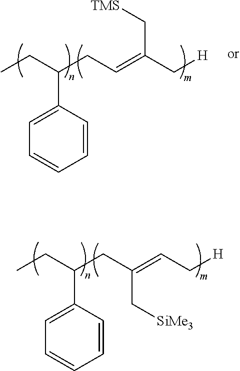

and abbreviated PS-b-PTMSI.

1,3-bis(diphenylphosphino)propane nickel (II) chloride is represented by the following structure:

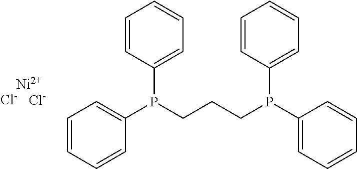

and abbreviated NiL₂Cl₂.

Styrene (which is indicated by “S” or “St”) is represented by the following structure:

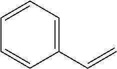

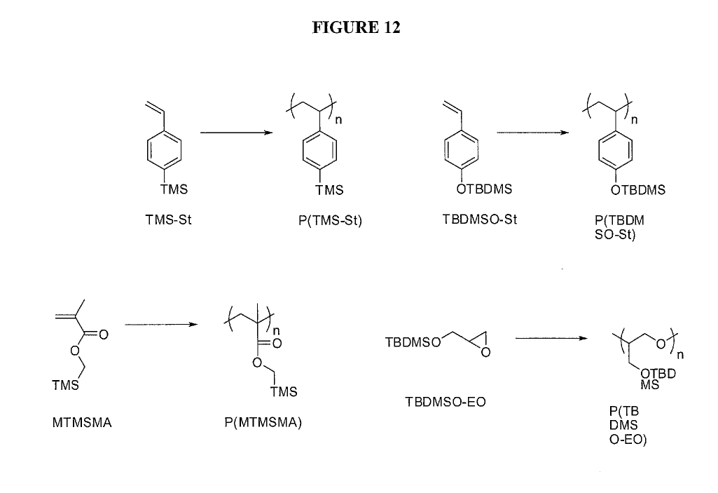

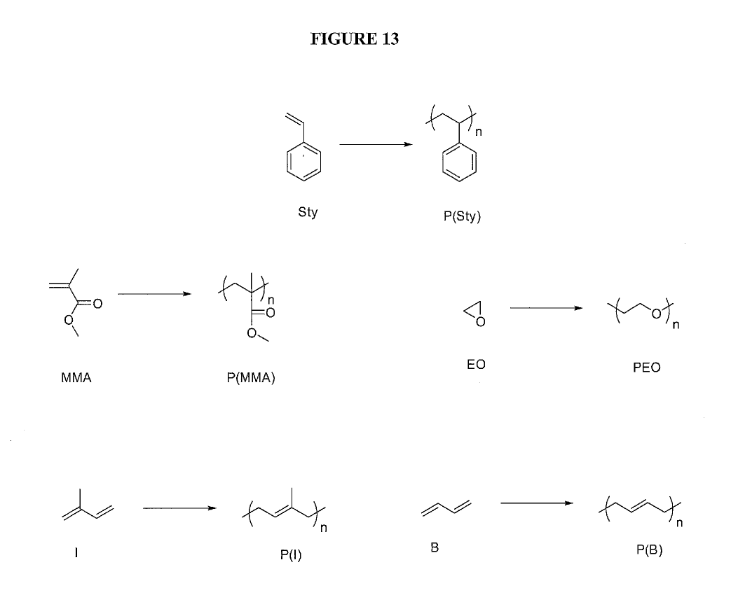

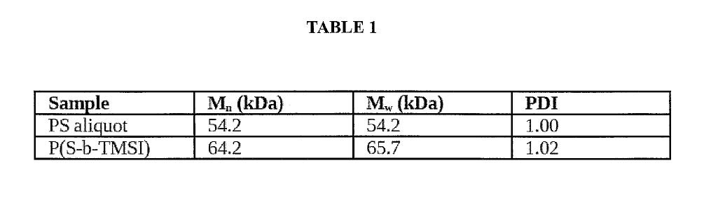

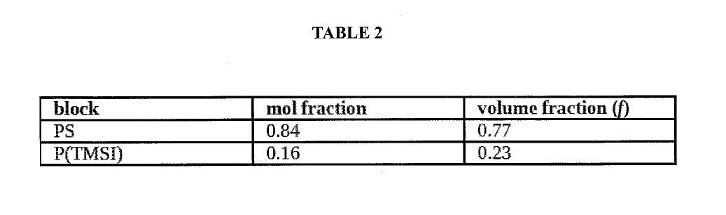

The present invention also contemplates styrene “derivatives” where the basic styrene structure is modified, e.g. by adding substituents to the ring (but preferably maintaining the vinyl group for polymerization). Derivatives of any of the compounds shown in FIGS. 12 and 13 can also be used. Derivatives can be, for example, hydroxy-derivatives, oxo-derivatives or halo-derivatives. As used herein, “hydrogen” means —H; “hydroxy” means —OH; “oxo” means ═O; “halo” means independently —F, —Cl, —Br or —I.

P-methylstyrene is an example of a styrene derivative and is represented by the following structure:

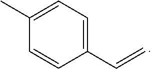

P-chlorostyrene is another example of a styrene haloderivative and is represented by the following structure:

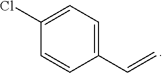

Trimethyl(4-vinylphenyl)silane is another example of a styrene derivative and is represented by the following structure:

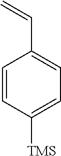

and abbreviated TMS-St and whose polymeric version is

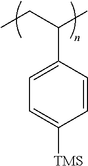

and is abbreviated P(TMS-St).

Tert-butyldimethyl(4-vinylphenoxy)silane is another example of a styrene derivative and is represented by the following structure:

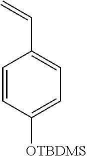 [SMILES: C=Cc1ccc(O[Si](C)(C)C(C)(C)C)cc1]

and abbreviated TBDMSO-St and whose polymeric version is

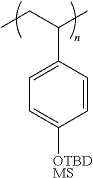

and is abbreviated P(TBDMSO-St).

Tert-butyldimethyl(oxiran-2-ylmethoxy)silane is an example of a silicon containing compound and is represented by the following structure:

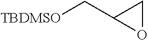 [SMILES: CC(C)(C)[Si](C)(C)OCC1CO1]

and is abbreviated TBDMSO-EO and whose polymeric version is

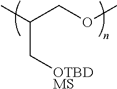

and is abbreviated P(TBDMSO-EO).

1,1-diphenylethene is represented by the following structure:

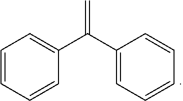

Methacryloxymethyltrimethylsilane is represented by the following structures:

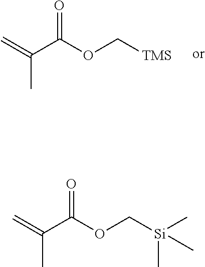

and abbreviated (MTMSMA) and whose polymeric version is

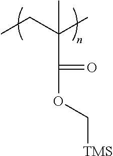

and is abbreviated P(MTMSMA).

Diphenyl ethylene end-capped polystyrene anion is represented by the following structure:

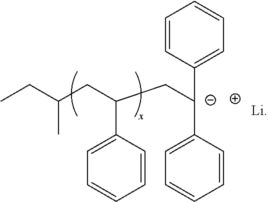

Polystyrene-block-polymethacryloxymethyltrimethylsilane PS-b-P(MTMSMA) is represented by the following structure:

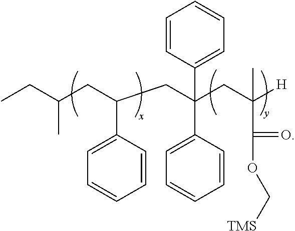

For scientific calculations, room temperature (rt) is taken to be 21 to 25 degrees Celsius, or 293 to 298 kelvins (K), or 65 to 72 degrees Fahrenheit.

It is desired that the silicon-containing copolymer be used to create “nanostructures” “nanofeatures” or “physical features on a nanometer scale” on a surface with controlled orientation. These physical features have shapes and thicknesses. For example, various nanostructures can be formed by components of a block copolymer, such as vertical lamellae, in-plane cylinders, and vertical cylinders, and may depend on film thickness, surface treatment, and the chemical properties of the blocks. In a preferred embodiment, said cylindrical structures being substantially vertically aligned with respect to the plane of the first film. Orientation of structures in regions or domains at the nanometer level (i.e. “microdomains” or “nanodomains”) may be controlled to be approximately uniform, and the spatial arrangement of these structures may also be controlled. For example, in one embodiment, domain spacing of the nanostructures is approximately 50 nm or less. The methods described herein can generate structures with the desired size, shape, orientation, and periodicity. Thereafter, in one embodiment, these structures may be etched or otherwise further treated.

### DETAILED DESCRIPTION OF THE INVENTION

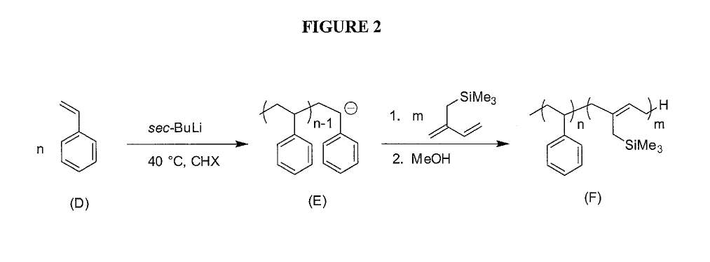

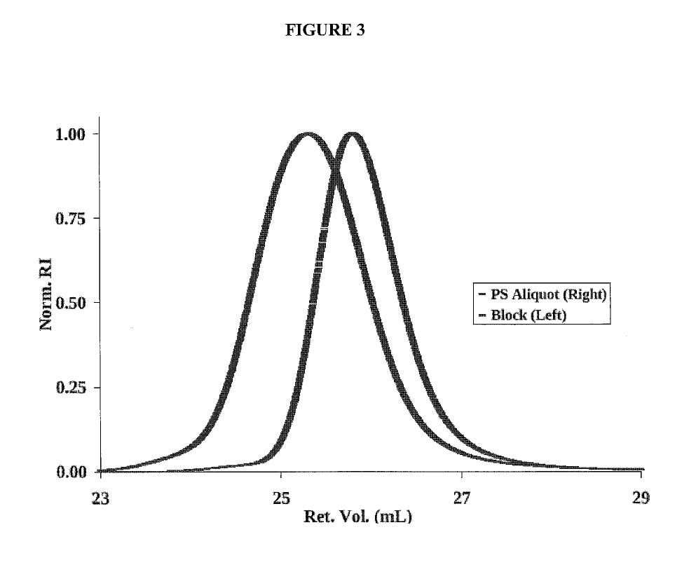

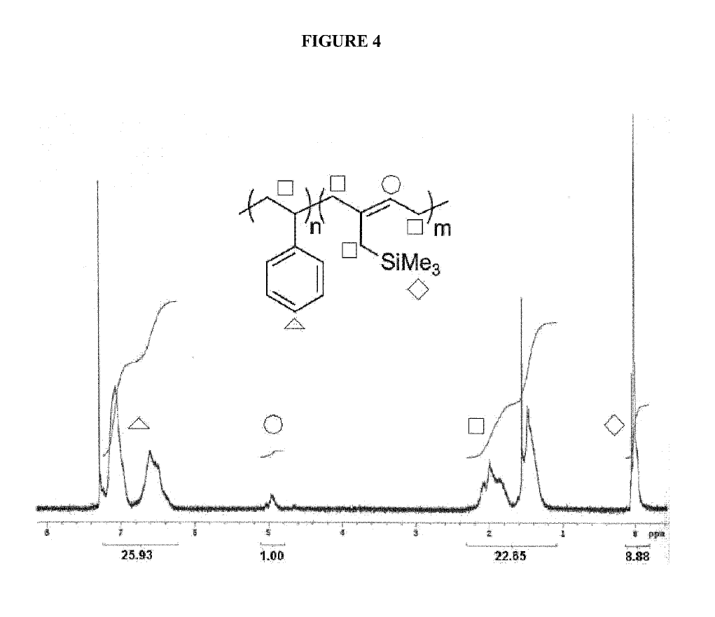

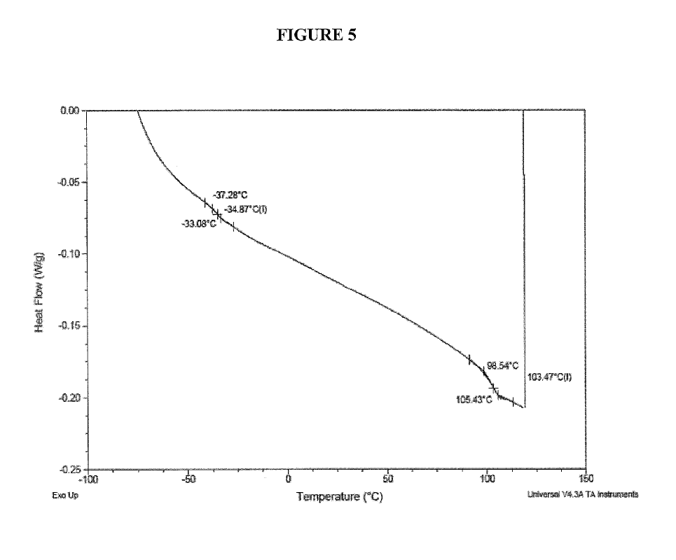

Due to the need for nanofeatures that can be etched, silicon-containing monomers were pursued. It is not intended that the present invention be limited by the nature of the silicon-containing monomer or that the present invention be limited to specific block polymers. However, to illustrate the invention, examples of various silicon-containing monomers and copolymers are provided. In one embodiment, a monomer trimethyl(2-methylenebut-3-enyl)silane was synthesized. After purification over nBuLi, isoprene trimethyl(2-methylenebut-3-enyl)silane was successfully added on to a living polystyrene (PS) anion (E) in cyclohexane (FIG. 2). ¹H-NMR analysis showed a mol ratio of 83:17 Sty:TMSI (FIG. 4). Using the density of PS previously reported in the literature [11], and assuming the density of PTMSI is similar to that of polyisoprene (PI), the volume fraction of PS is approximated at 0.77. Small changes in the density of PTMSI produce relatively small changes in the volume fraction of PTMSI. According to literature [12], P(S-b-I) with fPI=0.24 produces cylinders of PI, therefore a cylindrical morphology is expected. GPC determined the PDI of the PS aliquot and PS-b-PTMSI to be 1.00 and 1.02, respectively with a total Mn of 65.7 kDa (FIG. 3). DSC traces of the polymer showed two Tgs (FIG. 5): one at 103° C., which is consistent with reported PS values, and another at −34° C., which is assumed to that of the PTMSI block. The reported Tg for PI is −73° C, 44 but due to the steric bulk of the TMS group, this number seems to be reasonable.

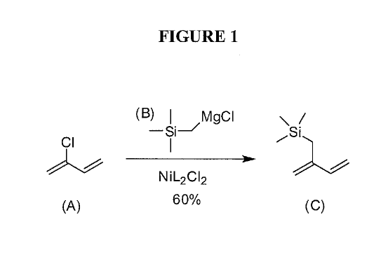

TMSI was successfully synthesized in good yield by a Kumada coupling reaction [10, 13] of chloroprene with (trimethylsilyl)methylmagnesium chloride (FIG. 1). Anionic polymerization was selected for the diblock copolymer synthesis because of its capability to provide narrow polydispersity and its scalability. The diblock copolymer synthesis was successfully conducted in cyclohexane (FIG. 2) with good control of molecular weight and polydispersity (Table 1). The gel permeation chromatogram shown in FIG. 3 demonstrates the successful growth of PS-b-PTMSI. The ¹H NMR spectrum (FIG. 4) shows a molar ratio of 0.84:0.16 PS:P(TMSI) when integrating the five aromatic styrene protons against both the single olefin proton in the backbone of the P(TMSI) block and the 9 TMS protons (Table 2). Using the previously reported density of PS [11] and assuming the density of P(TMSI) is similar to that of polyisoprene (PI), the volume fractions (f) of each block were calculated. Fortunately, small changes in the density of P(TMSI) produce relatively small changes in the volume fraction of P(TMSI). According to existing literature [12], P(S-b-I) with f_{PI}=0.24 produces cylinders of PI, therefore a cylindrical morphology of the P(TMSI) block is expected.

Colburn et al conducted a series of experiments that concluded a formulation with a minimum of approximately 12 wt % Si can serve as an etch barrier under standard O₂ RIE conditions versus PS [6]. Therefore, a block copolymer (BC) was designed that contained over 12 wt % silicon in one block but was all hydrocarbons (i.e. lacking silicon) in the other. This would provide the etch selectivity to yield a 3-D pattern of self-assembled features.

### General Materials and Methods

Reagents. All reagents were purchased from Sigma-Aldrich Chemical Co. and used without further purification unless otherwise stated. AP410 and AP310 were purchased from AZ Clariant. THF was purchased from JT Baker. Chloroprene 50 wt % in xylenes was purchased from Pfaltz & Bauer. Cyclohexane was purified with a Pure Solv MD-2 solvent purification system.

Instrumentation. All ¹H and ¹³C NMR spectra were recorded on a Varian Unity Plus 400 MHz instrument. All chemical shifts are reported in ppm downfield from TMS using the residual protonated solvent as an internal standard (CDCl₃, ¹H 7.26 ppm and ¹³C 77.0 ppm). Molecular weight and polydispersity data were measured using an Agilent 1100 Series Isopump and Autosampler and a Viscotek Model 302 TETRA Detector Platform with 3 Iseries Mixed Bed High MW columns against polystyrene standards. HRMS (CI) was obtained on a VG analytical ZAB2-E instrument. IR data were recorded on a Nicolet Avatar 360 FT-IR and all peaks are reported in cm⁻¹. Glass transition temperatures (T_{g}) were recorded on a TA Q100 Differential Scanning Calorimeter (DSC).

### EXAMPLE 1

Monomer (TMSI). In a modification of a procedure from Sakurai [13], a 250 mL RBF with condenser was charged with freshly ground Mg turnings (2.2 g, 92.2 mmol), a catalytic amount of dibromoethane, diethyl ether (100 mL), and a stir bar. After stirring for 15 min at rt, the reaction mixture was brought to reflux, and chloromethyltrimethylsilane (10.6 mL, 76.8 mmol) was added drop-wise over 30 min. In a separate 1 L Round bottom flask (RBF) with addition funnel, a mixture of 1,3-bis(diphenylphosphino)propane nickel (II) chloride (1.3 g, 2.3 mmol), freshly distilled chloroprene (9.0 mL, 97.6 mmol, bp=58-61° C., 760 torr), and diethyl ether (500 mL) was stirred at 0° C. After nearly complete Mg consumption (2 h), the pale-gray Grignard solution was cooled, added drop-wise to the dark-red, chloroprene mixture over 30 min and stirred overnight at room temperature (rt). The yellow solution was quenched with H₂O (500 mL) and extracted with ether (3×250 mL); the organic layers were combined, dried over MgSO₄, filtered and concentrated in vacuo. Trimethyl-(2-methylenebut-3-enyl)silane (TMSI) was isolated by distillation (57-60° C., 66 torr) in moderate yield (6.5 g, 60%) as a clear liquid; ¹H NMR (CDCl₃) δ ppm: 6.380 (ddd, J=17.6, 10.8, 0.4 Hz, 1H), 5.121 (dd, J=17.6, 0.4 Hz, 1H), 5.052 (dd, J=10.4, 0.4 Hz, 1H), 4.903 (m, 1H), 4.794 (s, 1H), 1.711 (d, J =0.8 Hz, 2H), 0.007 (s, 9H); ¹³C-NMR (CDCl₃) δ ppm: 144.141, 139.915, 114.142, 113.606, 21.190, −1.250; IR (NaCl) cm⁻¹: 3084, 2955, 2897, 1588, 1248, 851; HRMS (CI) 140.1021 calc, 140.1023 found.

Purifications. All purifications and polymerizations were performed under an Ar atmosphere using standard Schlenk techniques. [14] Styrene was vacuum distilled twice from di-n-butylmagnesium. TMSI was vacuum distilled twice from n-butyllithium. Cyclohexane was purified with a Pure Solv MD-2 solvent purification system. The cyclohexane was run through A-2 alumina to remove trace amounts of water followed by a supported Q-5 copper redox catalyst to remove oxygen [15].

Polymer. The styrene polymerization was initiated with secbutyllithium at 40° C. in cyclohexane. After 12 h, a 5 mL aliquot of polystyrene (PS) was extracted from the reactor and terminated with degassed methanol. Purified TMSI monomer was then added to the reactor drop-wise and reacted for 12 h, followed by addition of degassed methanol to quench the living anions. The block copolymer was precipitated in methanol, filtered and freeze dried in a 10 wt % benzene solution with 0.25 wt % butylated hydroxytoluene inhibitor to prevent oxidative degradation of the P(TMSI) backbone.

### EXAMPLE 2

### Synthesis of PS-b-PTMSI

Due to the problems associated with styrene derivatives, monomer trimethyl(2-methylenebut-3-enyl)silane was synthesized. After purification over nBuLi, isoprene trimethyl(2-methylenebut-3-enyl)silane was successfully added on to a living polystyrene (PS) anion in cyclohexane (FIG. 2). ¹H-NMR analysis showed a mol ratio of 83:17 Sty:TMSI (FIG. 4). Using the density of PS previously reported in the literature [11], and assuming the density of PTMSI is similar to that of polyisoprene (PI), the volume fraction of PS is approximated at 0.77. Small changes in the density of PTMSI produce relatively small changes in the volume fraction of PTMSI. According to existing literature 43, P(S-b-I) with fPI=0.24 produces cylinders of PI, therefore a cylindrical morphology is expected. GPC determined the PDI of the PS aliquot and PS-b-PTMSI to be 1.00 and 1.02, respectively with a total Mn of 65.7 kDa (FIG. 3). DSC traces of the polymer showed two Tgs (FIG. 5): one at 103° C., which is consistent with reported PS values [16], and another at −34° C., which is assumed to that of the PTMSI block. The reported Tg for PI is −73° C. [16], but due to the steric bulk of the TMS group, this number seems to be reasonable.

### EXAMPLE 3

### Synthesis of Trimethyl-(2-methylene-but-3-enyl)silane

In a modified procedure from Sakurai [13], a 250 mL RBF with condenser was charged with freshly ground Mg (2.2 g, 92.2 mmol), a catalytic amount of dibromoethane, diethyl ether (100 mL), and a stir bar. After stirring for 15 min at rt, the reaction mixture was brought to reflux, and chloromethyltrimethylsilane (10.6 mL, 76.8 mmol) was added drop-wise over 30 min. In a separate 1 L RBF with addition funnel, a mixture of 1,3-Bis(diphenylphosphino)propane nickel (II) chloride (1.3 g, 2.3 mmol), freshly distilled chloroprene (9.0 mL, 97.6 mmol, bp=58-61° C., 760 ton), and diethyl ether (500 mL) was stirred at 0° C. After nearly complete Mg consumption (2 h), the pale-gray Grignard solution was cooled, added drop-wise to the dark-red, chloroprene mixture over 30 min, and stirred overnight at rt. The yellow product was quenched with H₂O (500 mL) and extracted with ether (3×250 mL); the organic layers were combined, dried over MgSO₄, filtered, and concentrated in vacuo. Monomer 5.9 was isolated by distillation (57-60° C., 66 ton) as a clear liquid in moderate yield (6.5 g, 60%); ¹H NMR (CDCl₃)_ppm: 6.380 (ddd, J=17.6, 10.8, 0.4 Hz, 1H), 5.121 (dd, J=17.6, 0.4 Hz, 1H), 5.052 (dd, J=10.4, 0.4 Hz, 1H), 4.903 (m, 1H), 4.794 (s, 1H), 1.711 (d, J=0.8 Hz, 2H), 0.007 (s, 9H); ¹³C-NMR (CDCl₃)_ppm: 144.141, 139.915, 114.142, 113.606, 21.190, −1.250; IR (NaCl) cm⁻¹: 3084, 2955, 2897, 1588, 1248, 851; HRMS (CI) 140.1021 calc, 140.1023 found.

### EXAMPLE 4

### Block Co-Polymer (BC) Purification

All reactions and purification were conducted under Ar atmosphere via standard Schlenk line techniques [14]. All glassware was flame dried and purged with argon five times prior to exposure to any solvent or monomer. Purification agents, n-butyllithium (2.5 M solution in hexanes, Aldrich), and dibutylmagnesium (1 M solution in heptane, Aldrich) were received as solutions, and the solvents were removed using vacuum, prior to mixing with monomers. Exposure to air was prevented by storing and handling the reagent bottles under argon atmosphere inside a dry-box. Lithium chloride (LiCl, Fluka) was stored in a 120° C. oven and repeatedly flame dried and purged when placed inside the reactor. 1,1′-Diphenylethylene (DPE) (97%, Aldrich) was freeze-dried and vacuumdistilled twice over n-butyllithium and stored under argon atmosphere inside a dry-box. DPE, which is a high boiling liquid (bp 270-272° C.) was distilled at 140-160° C. under continuous vacuum. High-purity Argon, used for maintain inert conditions, was passed through an OMI-2 organometallic Nanochem® resin indicator/purification column (Air Products). Methanol (reagent grade, Aldrich) used as termination reagent, was degassed by sparging with argon for 45 min for removing air (particularly oxygen), which can potentially couple “living” polymer chains leading to undesired products. All other chemicals were used as purchased. Styrene (99%, 10-15 ppm p-tert-butylcatechol inhibitor, Aldrich) was freezedried and then purified by two successive distillations over solvent-dried dibutylmagnesium (0.1 mmol/g styrene) at 40° C. for 2 h. The styrene burette was covered with aluminum foil to prevent photopolymerization and stored in a freezer. When ready for a reaction, the monomer was freeze-dried twice. Trimethyl-(2-methylene-but-3-enyl)silane was freeze-dried, and then dried over n-BuLi twice for at least 1 h at rt. After distilling a burrette, the monomer was freeze dried and used immediately. Methacryloxymethyltrimethylsilane (Gelest, SIM6485.5) was filtered through basic alumina on a bench top open of the air, and then freeze-dried in a solvent flask. After drying over calcium hydride two times for at least 1 h at rt, the monomer was distilled into a burrette. The monomer was covered in foil and stored in the freezer for up to two days.

### EXAMPLE 5

### PS-b-PTMSI

Trimethyl-(2-methylene-but-3-enyl)silane was freeze-dried, and then dried over n-BuLi twice for at least 1 h at rt. After distilling a burrette, the monomer was freeze dried and used immediately.

A 500 mL reactor was loaded with a stir bar, flame dried, and cyclohexane was added into the reactor via a solvent flask. The total volume of cyclohexane used was set to so that the final concentration was 5 wt % monomer. After heating the reactor to 40° C., sec-BuLi was added and stirred for 30 min to ensure a homogenous solution. Approximately 20 drops of purified styrene was then added to the reaction via an airlock and a burrette. The color of the solution slowly turned orange, and after a 20 min seeding period, the remaining styrene was added. After stirring overnight, 20 drops of TMSI was added via the airlock and a burrette. After a 20 min of seeding, the remaining TMSI was added to the colorless reaction. To quench the reaction, degassed methanol (5 mL) was added to the reaction and stirred for 30 min.

### EXAMPLE 6

### PS-b-P(MTMSMA)

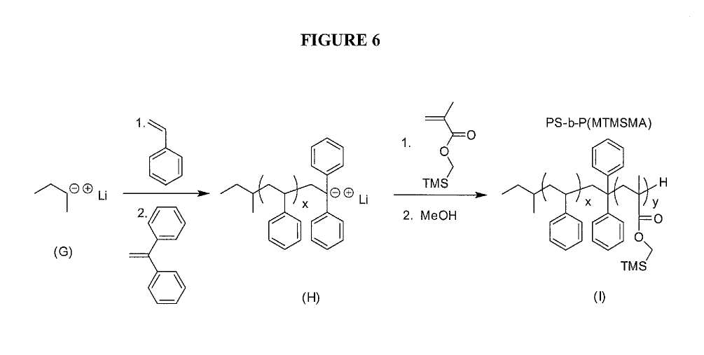

A silicon containing methacryloxymethyltrimethylsilane (MTMSMA) is commercially available from Gelest, Inc. Due to its higher MW and boiling point compared to MMA, the purification proved to be difficult. During the last distillation to remove alcohols, trioctylaluminum initiated MTMSMA polymerization. Attempts to remove alcohols by sodium hydride also led to polymerization. It was determined that alcohols could be removed by passing the monomer through an alumina plug, and then subjected to freeze, pump, thaw cycles and distillation over calcium hydride. This monomer was successfully incorporated PS-b-P(MTMSMA) (FIG. 6).

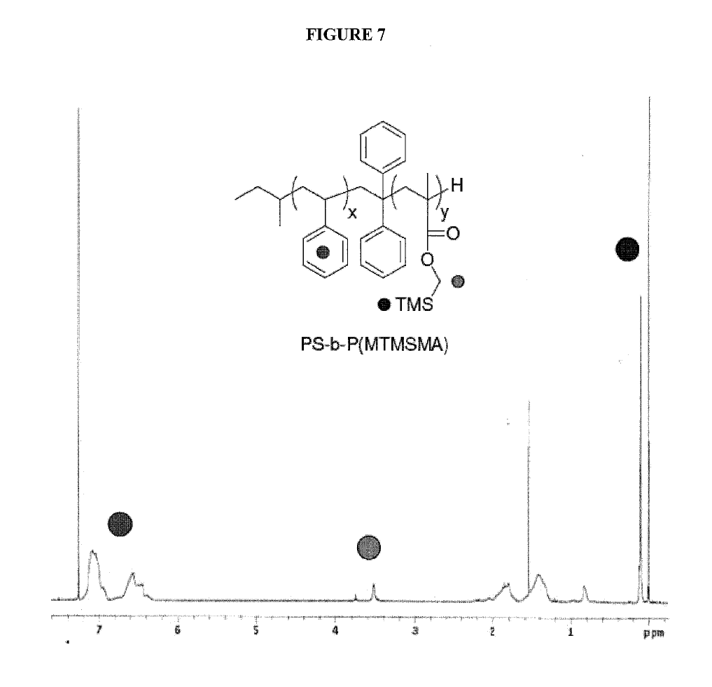

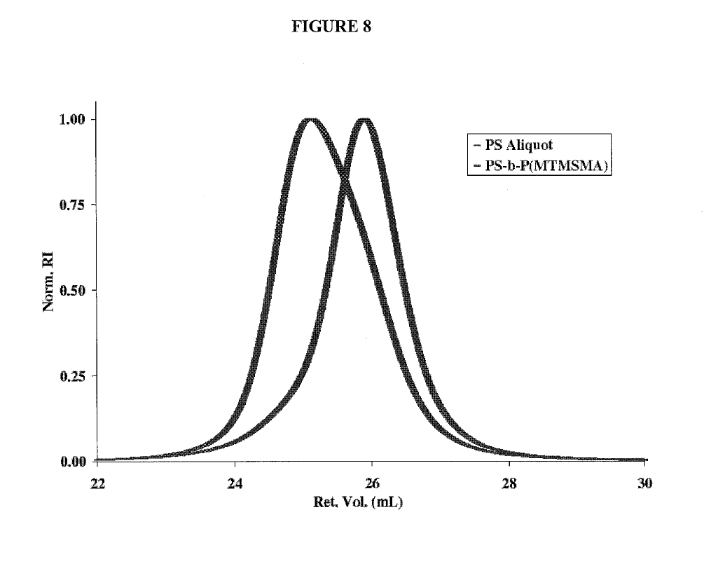

¹H NMR analysis showed a mol ratio of 73:27 Sty:MTMSMA (FIG. 7). Using the density of PS previously reported in the literature 12 and assuming the density of PMTMSMA is similar to that of PMMA, the volume fraction of PS is approximated at 0.66. Similarly to PS-b-PTMSI, small changes in the assumed density of P(MTMSMA) produce relatively small changes in the its volume fraction. According to the literature, 11 this volume fraction should yield a cylindrical morphology. GPC determined the PDI of the PS aliquot and PS-b-PTMSI both to be 1.17. The Mn of the PS aliquot and final precipitated block was 60.0 and 75.2 kDa, respectively (FIG. 8).

### EXAMPLE 7

### Synthesis of PS-b-P MTMSMA

Methacryloxymethyltrimethylsilane (MTMSMA) (Gelest, SIM6485.5) was filtered through basic alumina on a bench top open of the air, and then freeze-dried in a solvent flask. After drying over calcium hydride two times for at least 1 h at rt, the monomer was distilled into a burrette. The monomer was covered in foil and stored in the freezer for up to two days.

A 500 mL reactor was loaded with a stir bar and 5 molar equivalents of LiCl to initiator. LiCl suppresses side reactions during methacryloxymethyltrimethylsilane (MTMSMA) propagation [17]. Purified THF was added into the reactor via a solvent flask, and the reactor was cooled to −72° C. in a dry ice/IPA bath. The total volume of THF used was set to so that the final concentration was 5 wt % monomer. After the solution temperature was stabilized at −72° C., secBuLi was added and stirred for 5 min. Approximately 20 drops of purified styrene was then added to the reaction via an airlock and a burrette. The color of the solution immediately turned orange, and after a 20 min seeding period, the remaining styrene was added. This was stirred for 4 h followed by addition of 5 molar equivalents of DPE to initiator. This addition turned the reaction a deep red. After 3 h of stirring, 20 drops of MTMSMA was added to seed the MTMSMA via the airlock and a burrette, and this caused the reaction to turn colorless. The reaction was stirred for 4 h after the remaining MTMSMA was added. To quench the reaction, degassed methanol (5 mL) was added to the reaction and stirred for 45 min.

### EXAMPLE 8

### Small Angle X-ray Scattering

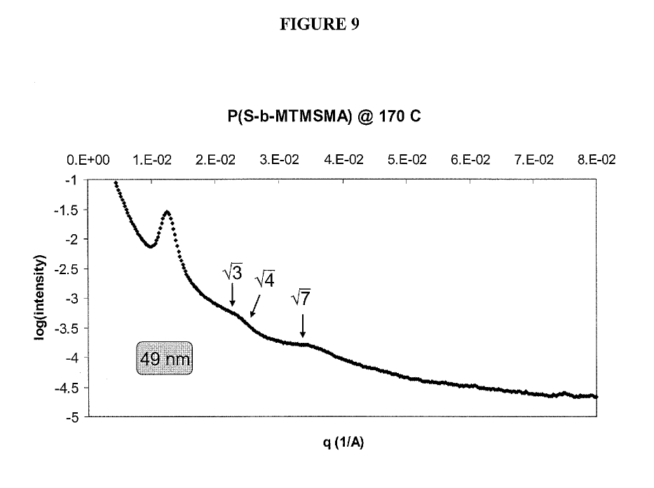

A sample of PS-b-P(MTMSMA) was analyzed via small angle X-ray scattering (SAXS). The data definitively show this block copolymer is phase separated at the nanoscale and that χN is of a sufficient value to induce order. The resulting Bragg's diffraction pattern displayed maxima at √3, √4, √7, indicative of a hexagonally packed cylindrical morphology. The domain spacing was calculated to be 49 nm. See FIG. 9.

### EXAMPLE 9

### Solvent Annealing of PS-b-P(MTMSMA)

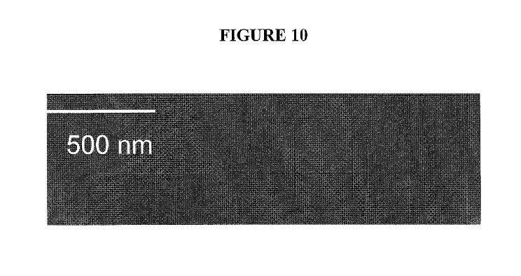

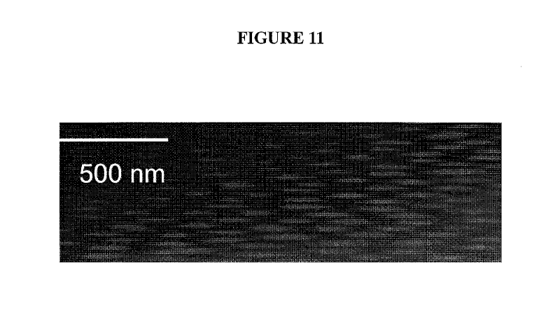

Thin films were spin coated on freshly oxidized wafers with a 1 wt % solution of PS-b-P(MTMSMA) in toluene. The wafers were then annealed under a saturated atmosphere of acetone or THF overnight in a covered glass petri dish. The resulting films were analyzed via AFM, and the images show both parallel (FIG. 10) and perpendicularly (FIG. 11) oriented cylinders depending on the solvent and film thickness. The size of the cylinders in these images is approximately 50 nm, which is consistent with the SAXS data.

### REFERENCES

1. Ross, C. A. (2001) Patterned Magnetic Recording Media, Annu. Rev. Mater Res. 31, 203-238.
2. Yang, X., Xu, Y., Seiler, C., Wan, L., and Xiao, S. (2008) Toward 1 Tdot/In.² Nanoimprint Lithography for Magnetic Bit-Patterned Media: Opportunities and Challenges J. Vac. Sci. Technol. 26, 2604-2610
3. Ruiz, R., Kang, H., Detcheverry, F. A., Dobisz, E., Kercher, D. S., Albrecht, T. R., de Pablo, J. J., and Nealey, P. F. (2008) Density Multiplication and Improved Lithography by Directed Block Copolymer Assembly, Science 321, 936-939.
4. Bates, F. S., and Fredrickson, G. H. (1990) Block Copolymer Thermodynamics. Theory and Experiment, Annu. Rev. Phys. Chem. 41, 525-557.
5. Li, M., and Ober, C. K. (2006) Block Copolymer Patterns and Templates, Mater. Today 9, 30-39.
6. Colburn, M., Grot, A., Amistoso, M. N., Choi, B. J., Bailey, T. C., Ekerdt, J. G., Sreenivasan, S. V., Hollenhorst, J., and Willson, C. G. (2000) Step and Flash Imprint Lithography for Sub-100-Nm Patterning, Proc. SPIE-Int. Soc. Opt. Eng. 3997, 453-457.
7. Kim, H.-C., Jia, X., Stafford, C. M., Kim, D. H., McCarthy, T. J., Tuominen, M., Hawker, C. J., and Russell, T. P. (2001) A Route to Nanoscopic Sio₂ Posts Via Block Copolymer Templates, Adv. Mater 13, 795-797.
8. Nagarajan, S., Li, M., Pai, R. A., Bosworth, J. K., Busch, P., Smilgies, D.-M., Ober, C. K., Russell, T. P., and Watkins, J. J. (2008) An Efficient Route to Mesoporous Silica Films with Perpendicular Nanochannels, Adv. Mater 20, 246-251.
9. Lammertink, R. G. H., Hempenius, M. A., Enk, J. E. v. d., Chan, V. Z.-H., Thomas, E. L., and Vancso, G. J. (2000) Nanostructured Thin Films of Organic-Organometallic Block Copolymers: One-Step Lithography with Poly(Ferrocenylsilanes) by Reactive Ion Etching, Adv. Mater 12, 98-103.
10. Tamao, K., Sumitani, K., and Kumada, M. (1972) Selective Carbon-Carbon Bond Formation by Cross-Coupling of Grignard Reagents with Organic Halides. Catalysis by Nickel-Phosphine Complexes, Journal of the American Chemical Society 94, 4374-4376.
11. Fetters, L. J., Lohse, D. J., Richter, D., Witten, T. A., and Zirkel, A. (1994) Connection between Polymer Molecular Weight, Density, Chain Dimensions, and Melt Viscoelastic Properties, Macromolecules 27, 4639-4647.
12. Khandpur, A. K., Foerster, S., Bates, F. S., Hamley, I. W., Ryan, A. J., Bras, W., Almdal, K., and Mortensen, K. (1995) Polyisoprene-Polystyrene Diblock Copolymer Phase Diagram near the Order-Disorder Transition, Macromolecules 28, 8796-8806.
13. Sakurai, H., Hosomi, A., Saito, M., Sasaki, K., Iguchi, H., Sasaki, J.-I., and Araki, Y. (1983) Chemistry of Organosilicon Compounds—165: 2-Trimethylsilyl-Methyl-1,3-Butadiene—a Versatile Building Block for Terpene Synthesis, Tetrahedron 39, 883-894.
14. Uhrig, D., and Mays, J. W. (2005) Experimental Techniques in High-Vacuum Anionic Polymerization, J. Polym. Sci. A. 43, 6179-6222.
15. Pangborn, A. B., Giardello, M. A., Grubbs, R. H., Rosen, R. K., and Timmers, F. J. (1996) Safe and Convenient Procedure for Solvent Purification, Organometallics 15, 1518-1520.
16. Odian, G. (2004) Principles of Polymerization, 4th ed ed., Wiley-Interscience, New York.
17. Allen, R. D., Long, T. E., and McGrath, J. E. (1986) Preparation of High Purity, Anionic Polymerization Grade Alkyl Methacrylate Monomers Polym. Bull. 15, 127-134.

1. A method of forming nanostructures on a surface, comprising:
a. providing a Polystyrene-block-polymethacryloxymethyltrimethylsilane copolymer and a surface;
b. spin coating said block copolymer on said surface to create a coated surface;
c. treating said coated surface under conditions such that nanostructures are formed on said surface; and
d. etching said nanostructure-containing coated surface.

2. The method of claim 1, wherein said nanostructures comprises cylindrical structures, said cylindrical structures being substantially vertically aligned with respect to the plane of the surface.

3. The method of claim 1, wherein said treating comprises exposing said coated surface to a saturated atmosphere of acetone or THF.

4. The method of claim 1, wherein said surface is on a silicon wafer.

5. The method of claim 1, wherein said surface is not pre-treated with a cross-linked polymer prior to step b).

6. The method of claim 1, wherein said surface is pre-treated with a cross-linked polymer prior to step b).

7. A method of synthesizing a silicon-containing block copolymer film, comprising:
a. providing first and second monomers, said first monomer comprising a silicon atom and said second monomer being a hydrocarbon monomer lacking silicon that can be polymerized;
b. treating said second monomer under conditions such that reactive polymer of said second monomer is formed;
c. reacting said first monomer with said reactive polymer of said second monomer under conditions such that said silicon-containing block copolymer is synthesized;
d. coating a surface with said block copolymer so as to create a block copolymer film;
e. treating said film under conditions such that nanostructures form; and
f. etching said film.

8. The method of claim 7, wherein said second monomer is styrene and said reactive polymer is reactive polystyrene.

9. The method of claim 8, wherein said reactive polystyrene is anionic polystyrene.

10. The method of claim 7, wherein said first monomer is trimethyl-(2-methylene-but-3-enyl)silane.

11. The method of claim 10, wherein said first monomer was synthesized in a Kumada coupling reaction of chloroprene and (trimethylsilyl)-methylmagnesium chloride.

12. The method of claim 8, wherein the conditions of step b) comprise polymerization in cyclohexane.

13. The method of claim 7, further comprising d) precipitating said silicon-containing block copolymer in methanol.

14. The method of claim 7, wherein said silicon-containing block copolymer is PS-b-PTMSI.

15. The method of claim 7, wherein said first monomer is a silicon-containing methacrylate.

16. The method of claim 15, wherein said first monomer is methacryloxymethyltrimethylsilane.

17. The method of claim 16, wherein said silicon-containing block copolymer is Polystyrene-block-polymethacryloxymethyltrimethylsilane.

18. The method of claim 7, wherein said second monomer is a methacrylate.

19. The method of claim 7, wherein said second monomer is an epoxide.

20. The method of claim 7, wherein said second monomer is a styrene derivative.

21. The method of claim 20, wherein said styrene derivative is p-methylstyrene.

22. The method of claim 20, wherein said styrene derivative is p-chlorostyrene.

23. The method of claim 7, wherein said nanostructures comprises cylindrical structures, said cylindrical structures being substantially vertically aligned with respect to the plane of the surface.

24. The method of claim 7, wherein said treating comprises exposing said coated surface to a saturated atmosphere of acetone or THF.

25. The method of claim 7, wherein said surface is on a silicon wafer.

26. The method of claim 7, wherein said surface is not pre-treated with a cross-linked polymer prior to step d).

27. The method of claim 7, wherein said surface is pre-treated with a cross-linked polymer prior to step d).

28. The method of claim 7, wherein a third monomer is provided and said block copolymer is a triblock copolymer.

29. The film made according to the process of claim 7.
